(19) United States
(12) Patent Application Publication
(10) Pub. No.: US 2004/0141389 A1
(43) Pub. Date: Jul. 22, 2004

(54) Solid state storage device and data storage method

(76) Inventors: David Murray Banks, Bristol (GB); James A. Davis, Richmond, VA (US); Jonathan Jedwab, Vancouver (CA)

Correspondence Address: HEWLETT-PACKARD COMPANY, Intellectual Property Administration, P.O. Box 272400, Fort Collins, CO, 80527-2400, US

(21) Appl. No.: 10/632,130

(22) Filed: Jul. 30, 2003

(30) Foreign Application Priority Data
Jul. 31, 2002 (GB) 0217797.0

(51) Int. Cl. G11C 7/00

(52) U.S. Cl. 365/200

(57) ABSTRACT

An MRAM solid-state storage device is disclosed having at least one array of magnetoresistive storage cells. The MRAM device includes a Reed-Solomon encoder arranged to encode original data to generate one or more codewords of length B symbols including 2T check symbols, using a generator polynomial G(x) of the form:

g(x)=(x+a^{L})(x+a^{L+1})(x+a^{L+2}) . . . (x+a^{L+2T-1})

where 0≦L<255 and T=16. This generator polynomial allows robust and reliable data storage despite limitations of current manufacturing techniques for MRAM devices, and also allows a relatively efficient physical device layout.

The present invention relates in general to a magnetoresistive solid-state storage device employing error correction coding (ECC). Also, the invention relates to a method for storing data in such a device.

A typical solid-state storage device comprises one or more arrays of storage cells for storing data. Existing semiconductor technologies provide volatile solid-state storage devices suitable for relatively short term storage of data, such as dynamic random access memory (DRAM), or devices for relatively longer term storage of data such as static random access memory (SRAM) or non-volatile flash and EEPROM devices. However, many other technologies are known or are being developed.

Recently, a magnetoresistive storage device has been developed as a new type of non-volatile solid-state storage device (see, for example, EP-A-0918334 Hewlett-Packard). The magnetoresistive solid-state storage device is also known as a magnetic random access memory (MRAM) device. MRAM devices have relatively low power consumption and relatively fast access times, particularly for data write operations, which renders MRAM devices ideally suitable for both short term and long term storage applications.

A problem arises in that MRAM devices are subject to physical failure, which can result in an unacceptable loss of stored data. In particular, currently available manufacturing techniques for MRAM devices are subject to limitations and as a result manufacturing yields of acceptable MRAM devices are relatively low. Although better manufacturing techniques are being developed, these tend to increase manufacturing complexity and cost. Hence, it is desired to apply lower cost manufacturing techniques whilst increasing device yield. Further, it is desired to increase cell density formed on a substrate such as silicon, but as the density increases manufacturing tolerances become increasingly difficult to control leading to higher failure rates and lower device yields.

A further problem arises in that it is desired to provide a device layout on a substrate such as silicon, which is both physically efficient and which is functional in use. Physical efficiency includes factors such as cell density and manufacturing efficiency. Functional features relate to ease with which data may be stored and retrieved in use, including access speed and reliability.

An aim of the present invention is to provide a method for storing data in an MRAM device (i.e. a solid-state storage device having at least one array of magnetoresistive storage cells), which balances the need for reliable data storage against the desire for physical efficiency.

According to a first aspect of the present invention there is provided a method for storing data in a solid state storage device having at least one array of magnetoresistive storage cells, the method comprising the steps of: encoding original data with a Reed-Solomon code to generate one or more codewords including 2T check symbols, using a generator polynomial g(x) of the form:

g(x)=(x+a^{L})(x+a^{L+1})(x+a^{L+2}) . . . (x+a^{L+2T-1}) where 0≦L<255 and T=16; and storing the one or more codewords in the at least one array of magnetoresistive storage cells.

Surprisingly, the generator polynomial defined above has a number of benefits. Firstly, the value T=16 allows a relatively large number of physical failures to affect any particular codeword, whilst maintaining reliable data storage. Also, it has been found that the generator polynomial produces codewords that allow an efficient physical device layout. Hence, this generator polynomial advantageously addresses both the problems of reliable data storage in the inherently unreliable MRAM devices, whilst also addressing the need for efficient device layout.

In the preferred embodiment, original data is received in sectors of length 512 bytes. This original data is used to generate four codewords using eight-bit symbols, where each codeword is of length up to B=160 symbols, including B−2T=128 information symbols and 2T=32 check symbols.

Preferably, the generator polynomial uses the value L=1. This value of L allows an efficient decoder design.

In an alternative embodiment, L=112. Here, it has been found that the generator polynomial is palandromic, leading to a smaller and more efficient encoder.

Preferably the method comprises dividing a sector of original data into a plurality of sub-sector units, and encoding each sub-sector unit to form one codeword.

In a preferred embodiment, the method comprises encoding a sector of original data of length 512 bytes to generate four codewords each of length 160 bytes including 128 information symbols and 2T=32 check symbols. Here, the method comprises storing the four codewords in a macro-array having a plurality of arrays of magnetoresistive storage cells. Ideally, the four codewords are stored across the macro-array to be accessible substantially simultaneously.

Preferably the method comprises reading the stored encoded data from the at least one array, and decoding the stored encoded data.

According to a second of the present invention there is provided a method of encoding data for storage in a solid state storage device comprising a macro-array formed of a plurality of arrays of magnetoresistive storage cells, the method comprising the steps of: receiving a sector of original data; dividing the sector of original data into a plurality of sub-sector units; encoding each sub-sector unit with a Reed-Solomon code to generate a codeword including 2T check symbols, using a generator polynomial g(x) of the form:

g(x)=(x+a^{L})(x+a^{L+1})(x+a^{L+2}) . . . (x+a^{L+2T-1})

where 0≦L<255 and T=16; and storing the one or more codewords in the macro-array of magnetoresistive storage cells.

Preferably the method comprises retrieving the stored codewords from the macro-array; decoding each codeword to provide a plurality of sub-sector units of decoded data; and assembling the decoded sub-sector units to provide a sector unit of decoded data.

According to a third aspect of the present invention there is provided a solid state storage device comprising: a Reed-Solomon encoder arranged to encode original data to generate one or more codewords including 2T check symbols, using a generator polynomial g(x) of the form:

g(x)=(x+a^{L})(x+a^{L+1})(x+a^{L+2}) . . . (x+a^{L+2T-1})

where 0≦L<255 and T=16; at least one array of magnetoresistive storage cells arranged to store the one or more generated codewords; and a Reed-Solomon decoder arranged to decode the stored one or more codewords to retrieve the original data.

For a better understanding of the invention, and to show how embodiments of the same may be carried into effect, reference will now be made, by way of example, to the accompanying diagrammatic drawings in which:

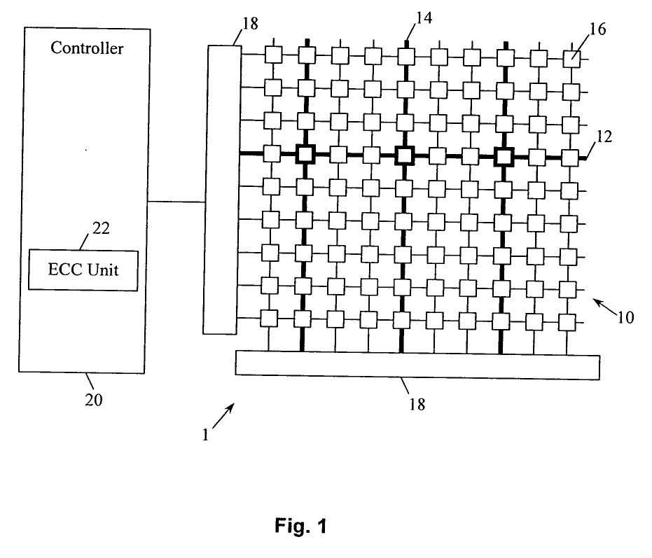

FIG. 1 is a schematic diagram showing a preferred MRAM device including an array of storage cells;

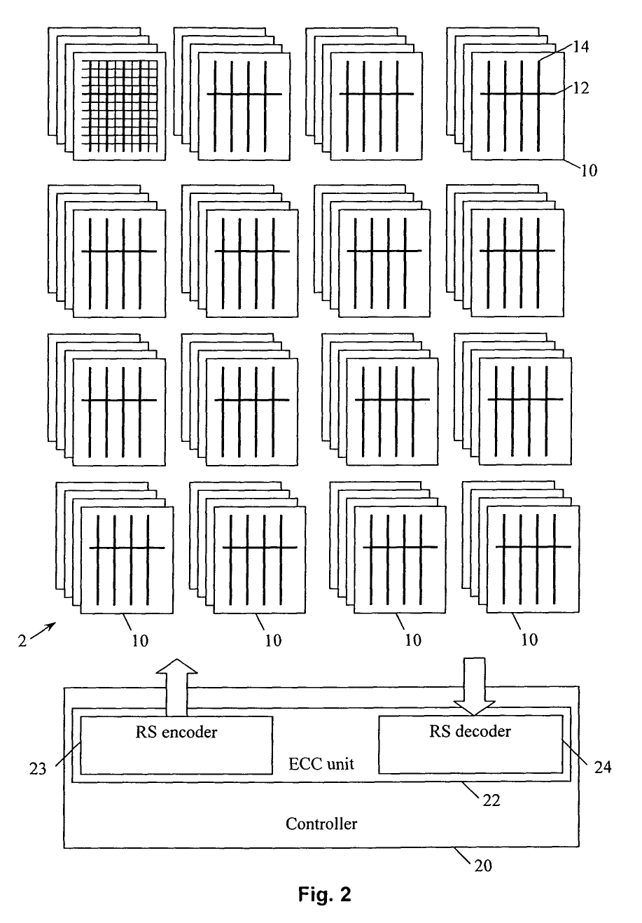

FIG. 2 shows a preferred MRAM device in more detail;

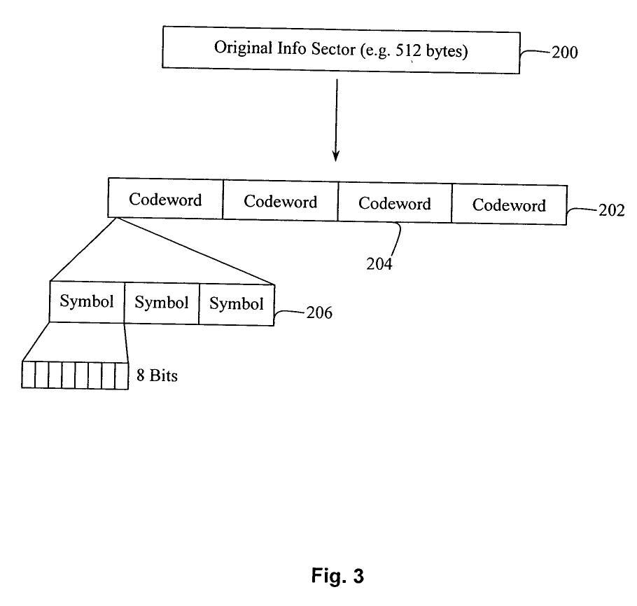

FIG. 3 shows a preferred logical data structure for error correction coding;

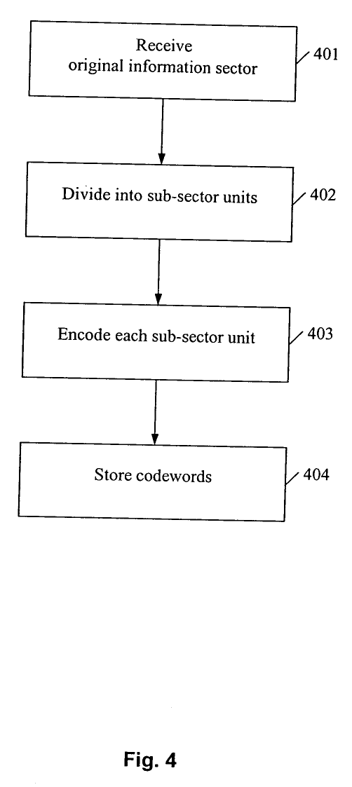

FIG. 4 shows a preferred method for storing data in the MRAM device.

To assist a complete understanding of the present invention, an example MRAM device will first be described with reference to FIGS. 1 and 2, including a description of the failure mechanisms found in MRAM devices. The error correction arrangements adopted in the preferred embodiments of the present invention aim to minimise the adverse effects of such physical failures and are described with reference to FIGS. 3 and 4.

FIG. 1 shows a simplified magnetoresistive solid-state storage device 1 comprising an array 10 of storage cells 16. The array 10 is coupled to a controller 20 which, amongst other control elements, includes an ECC coding and decoding unit 22. The controller 20 and the array 10 can be formed on a single substrate, or can be arranged separately. EP-A-0 918 334 (Hewlett-Packard) discloses one example of a magnetoresistive solid-state storage device which is suitable for use in preferred embodiments of the present invention.

In the preferred embodiment, the array 10 comprises of the order of 1024 by 1024 storage cells, just a few of which are illustrated. The storage cells 16 are each formed at an intersection between control lines 12 and 14. In this example control lines 12 are arranged in rows, and control lines 14 are arranged in columns. The control lines 12 and 14 are generally orthogonal, but other more complicated lattice structures are also possible. Suitably, the row and column lines 12, 14 are coupled to control circuits 18, which include a plurality of read/write control circuits. Depending upon the implementation, one read/write control circuit is provided per column, or read/write control circuits are multiplexed or shared between columns.

In a device access such as a write operation or a read operation, one row 12 and one or more columns 14 are selected by the control circuits 18 to access the required storage cell or cells 16 (or conversely one column and several rows, depending upon the orientation of the array). The selected cells 16, the selected row line 12, and the selected column lines 14, are each represented by bold lines in FIG. 1. The preferred MRAM device requires a minimum distance m, such as sixty-four cells, between the selected column lines 14 to minimise cross-cell interference. Given that each array 10 has rows of length l, such as 1024 storage cells, it is possible to access substantially simultaneously up to l/m=1024/64=16 cells from the array 10.

Each storage cell 16 stores one bit of data suitably representing a numerical value and preferably a binary value, i.e. one or zero. Suitably, each storage cell includes two films which assume one of two stable magnetisation orientations, known as parallel and anti-parallel. The magnetisation orientation affects the resistance of the storage cell. When the storage cell 16 is in the anti-parallel state, the resistance is at its highest, and when the magnetic storage cell is in the parallel state, the resistance is at its lowest. Suitably, the high resistance anti-parallel state defines a “0” logic state, and the low resistance parallel state defines a “1” logic state, or vice versa. In the preferred device, the resistance of each storage cell 16 is determined according to a phenomenon known as spin tunnelling and the cells are referred to as magnetic tunnel junction storage cells. The condition of the storage cell is determined by measuring the sense current (proportional to resistance) or a related parameter such as response time to discharge a known capacitance, which gives one or more parametric values for each storage cell. A logical value can then be derived from the obtained parametric value or values. Depending upon the nature and construction of the MRAM device, the read operation may comprise multiple steps or require combined read and rewrite actions.

FIG. 2 shows the preferred MRAM device in more detail. A macro-array 2 comprises a large plurality of individual arrays 10, each of which is formed as discussed above for FIG. 1. The use of plural arrays advantageously allows an MRAM device to be obtained of a desired overall data storage capacity, without the individual arrays 10 in themselves becoming so large that they are difficult to manufacture or control. For simplicity, FIG. 2 shows only a portion of the macro-array. Optionally, the MRAM device comprises more than one such macro-array.

As illustrated in FIG. 2, accessing the MRAM device 1 comprises selecting one row 12 in each of a plurality of arrays 10, and selecting plural columns 14 from each of the plurality of arrays to thereby select a plurality of storage cells 16. The accessed cells within each of the plurality of arrays correspond to a small portion of a unit of data. Together, the accessed cells from the macro-array provide a whole unit of data, such as a whole sector unit, or at least a substantial portion of the unit. Advantageously, each of the plurality of arrays are accessible substantially simultaneously. Therefore, device access speed for a read operation or a write operation is increased. This device access is conveniently termed a slice through the macro-array.

As shown in FIG. 2, it is convenient for the same row address and the same column addresses to be selected in each of the plurality of arrays. That is, a unit of data is stored across a plurality of arrays, using the same row and column addresses within each of the plurality of arrays.

Conveniently, it has been found that the arrays 10 can be manufactured in layers. In the example of FIG. 2, four arrays 10 are layered to form a stack. In the currently preferred embodiment, only one array within each stack can be accessed at any one time. Therefore, it is convenient that the plurality of arrays used to store a sector unit of data are each in different stacks (i.e. none of the selected plurality of arrays are in the same stack). Also, it is convenient to select arrays which are all in the same layer. Ideally, one array is selected from each stack, the arrays each being in the same layer within each stack. In the example of FIG. 2, the topmost array within each stack has been selected.

Although generally reliable, it has been found that failures can occur which affect the ability of the device to store data reliably in the storage cells 16. Physical failures within a MRAM device can result from many causes including manufacturing imperfections, internal effects such as noise in a read process, environmental effects such as temperature and surrounding electromagnetic noise, or ageing of the device in use. In general, failures can be classified as either systematic failures or random failures. Systematic failures consistently affect a particular storage cell or a particular group of storage cells. Random failures occur transiently and are not consistently repeatable. Typically, systematic failures arise as a result of manufacturing imperfections and ageing, whilst random failures occur in response to internal effects and to external environmental effects.

Failures are highly undesirable and mean that at least some storage cells in the device cannot be written to or read from reliably. A cell affected by a failure can become unreadable, in which case no logical value can be read from the cell, or can become unreliable, in which case the logical value read from the cell is not necessarily the same as the value written to the cell (e.g. a “1” is written but a “0” is read). The storage capacity and reliability of the device can be severely affected and in the worst case the entire device becomes unusable.

Failure mechanisms take many forms, and the following examples are amongst those identified:

1. Shorted bits—where the resistance of the storage cell is much lower than expected. Shorted bits tend to affect all storage cells lying in the same row and the same column.

2. Open bits—where the resistance of the storage cell is much higher than expected. Open bit failures can, but do not always, affect all storage cells lying in the same row or column, or both.

3. Half-select bits—where writing to a storage cell in a particular row or column causes another storage cell in the same row or column to change state. A cell which is vulnerable to half select will therefore possibly change state in response to a write access to any storage cell in the same row or column, resulting in unreliable stored data.

4. Single failed bits—where a particular storage cell fails (e.g. is stuck always as a “0”), but does not affect other storage cells and is not affected by activity in other storage cells.

These four example failure mechanisms are each systematic, in that the same storage cell or cells are consistently affected. Where the failure mechanism affects only one cell, this can be termed an isolated failure. Where the failure mechanism affects a group of cells, this can be termed a grouped failure.

Whilst the storage cells of the MRAM device can be used to store data according to any suitable logical layout, data is preferably organised into basic sub-units (e.g. bytes) which in turn are grouped into larger logical data units (e.g. sectors). A physical failure, and in particular a grouped failure affecting many cells, can affect many bytes and possibly many sectors. It has been found that keeping information about each small logical sub-unit (e.g. bytes) affected by physical failures is not efficient, due to the quantity of data involved. That is, attempts to produce a list of all such logical units rendered unusable due to at least one physical failure, tend to generate a quantity of management data which is too large to handle efficiently. Further, depending on how the data is organised on the device, a single physical failure can potentially affect a large number of logical data units, such that avoiding use of all bytes, sectors or other units affected by a failure substantially reduces the storage capacity of the device. For example, a grouped failure such as a shorted bit failure in just one storage cell affects many other storage cells, which lie in the same row or the same column. Thus, a single shorted bit failure can affect 1023 other cells lying in the same row, and 1023 cells lying in the same column—a total of 2027 affected cells. These 2027 affected cells may form part of many bytes, and many sectors, each of which would be rendered unusable by the single grouped failure.

In the current MRAM devices, grouped failures tend to affect a large group of storage cells, sharing the same row or column. This provides an environment which is very different to any prior storage devices, and in particular is unlike any prior solid-state storage devices.

Some improvements have been made in manufacturing processes and device construction to reduce the number of manufacturing failures and improve device longevity, but this usually involves increased manufacturing costs and complexity, and reduced device yields.

The preferred embodiments of the present invention employ error correction coding to provide a magnetoresistive solid-state storage device which is error tolerant, preferably to tolerate and recover from both random failures and systematic failures. Error correction coding involves receiving original information which it is desired to store and forming encoded data which allows errors to be identified and ideally corrected. The encoded data is stored in the solid-state storage device. At read time, the original information is recovered by error correction decoding the stored encoded data.

Referring to FIG. 2, the ECC coding and decoding unit 22 comprises an encoder 23, and a decoder 25. The operation of the encoder 23 will now be described in more detail, with reference to FIGS. 3 and 4.

FIG. 3 shows an example logical data structure used when storing data in the MRAM device 10. Original information 200 is received in predetermined units such as a sector comprising 512 bytes. The encoder 23 receives the sector 200 of original data and produces ECC encoded data, in the form of an encoded sector 202 comprising four codewords 204 each having a plurality of symbols 206. Each symbol is a multibit symbol, conveniently an 8-bit symbol.

Generally, a preferred encoding method comprises receiving a sector 200 of original data, encoding the original data to generate a plurality of codewords, and then storing the generated codewords in the arrays of magnetoresistive storage cells.

Here, the encoder 23 encodes the original data to generate the codewords 204, each including 2T check symbols, using a generator polynomial g(x) of the form:

g(x)=(x+a^{L})(x+a^{L+1})(x+a^{L+2}) . . . (x+a^{L+2T-1})

where 0≦L<255 and T=16.

In the preferred embodiment, each codeword has a length up to B=160 symbols, comprising 128 information symbols and 2T=32 check symbols. Hence, a sector of 512 original information bytes is stored as four codewords, each codeword of length 160 symbols having been generated from 512/4=128 information bytes.

Although the encoder 23 and the decoder 25 are designed to operate over a shortened Reed-Solomon code of length B=160, they are in principle compatible with any Reed-Solomon code derived from the same generator polynomial, up to and including the full length case where B=255.

Preferably, L=1. This value of L allows an efficient design of the decoder 25. In particular, selecting L=1 allows a more efficient evaluation of Formey's equations by avoiding one multiply action. Hence, selecting this value of L in the generator polynomial used during encoding allows savings to be made downstream, when retrieving stored data from the device.

In an alternative embodiment, L=112. Here, it has been found that the generator polynomial is palandromic, leading to an encoder 23 that is smaller and more efficient. Here, the encoder 23 can be only half-size, compared with the size required for any other (non-palandromic) value of L.

FIG. 4 shows the preferred encoding method in more detail. An original information sector 200 is received in step 401, comprising 512 bytes. The information sector is divided into four sub-sector units in step 402, each sub-sector unit comprising 128 information bytes. Each sub-sector unit is passed to the encoder 23 in turn. Each sub-sector unit is encoded, in step 403, using the generator polynomial noted above, to form a codeword 204. Therefore, the original information sector 200 results in four codewords 204. In step 404, these four codewords are stored in the arrays of magnetoresistive storage cells.

The decoder 25 is arranged corresponding to the encoder 23. The decoder 25 performs, generally, a reverse of the encoding method shown in FIG. 4. That is, the stored codewords are retrieved from the magnetoresistive storage cells. Each codeword is decoded to form a sub-sector unit of decoded data. The sub-sector units are then combined to form a retrieved information sector.

Referring again to FIG. 2, many design choices are available to the skilled person when laying out the arrays 10 on a suitable substrate during manufacture of the device. The preferred embodiment has been developed to address both the needs of data reliability, and physical efficiency.

Most conveniently, the number of arrays available in a macro-array 2 is matched to the size of a codeword 204 and an encoded sector 202. Here, the total number of arrays in a macro array are arranged such that, given the number of cells which can be substantially simultaneously accessed in one array, an encoded sector is stored using cells within all of the arrays of a macro array. Where the macro-array uses stacks, then all of the arrays in a single layer of the device are used to store a whole sector unit of data. In other preferred embodiments, it is convenient for a reciprocal integer fraction of a sector unit of data (e.g. one half or one third or one quarter of a sector unit) to be accessible substantially simultaneously. Multiple accesses (i.e. two, three or four accesses) are then used to store or retrieve the whole sector unit.

The preferred MRAM device employs a macro-array comprising 1280 arrays arranged 16 wide by 20 high, optionally with two or more stack layers. Ideally, there are 4 stack layers. Assuming that each array may simultaneously access 16 bits, i.e. 2 eight-bit symbols, a single slice through the macro-array therefore provides access to 16*20*2=640 symbols. These 640 symbols correspond to four codewords, each of length 640/4=160 symbols. Using the preferred generator polynomial, these four codewords 204 correspond to a sector 200 of original data.

Referring again to FIGS. 1 and 2, the eight bits corresponding to each symbol 206 are conveniently stored in eight storage cells 16, which can be termed a symbol group. A physical failure which directly or indirectly affects any of these eight storage cells in a symbol group can result in one or more of the bits being unreliable (i.e. the wrong value is read) or unreadable (i.e. no value can be obtained), giving a failed symbol.

Error correction decoding each block of stored ECC encoded data allows failed symbols 206 to be identified and corrected. Conveniently, decoding is performed independently for each block of ECC encoded data, i.e. for each codeword 204.

Advantageously, the preferred ECC scheme has been designed with a power sufficient to recover original information 200 from the encoded data in substantially all cases. Pictorially, each perfect codeword of ECC encoded data represents a point in space, and a reliably correctable form of that codeword lies within a “ball” having a radius corresponding to the maximum guaranteed power of the ECC encoding scheme. Very rarely, a block of encoded data is encountered which is affected by so many failures that the original information 200 is unrecoverable. Here, the RS decoder 25 is presented with a codeword which is so severely affected by physical failures that it lies outside the ball of all reliably correctable codewords. Also, even more rarely, the failures result in a mis-correct, where information recovered from the encoded data 202 is not equivalent to the original information 200. Even though the recovered information does not correspond to the original information, a mis-correct is not readily determined. Pictorially, the ECC decoding unit 22 is presented with a block of ECC encoded data which is so severely affected by physical failures that it lies inside an incorrect ball, i.e. not the ball corresponding to the perfect form of that codeword block of ECC encoded data. Here, the ECC scheme has been selected such that the probability of encountering an unrecoverable or mis-corrected codeword of ECC encoded data is extremely small, suitably of the order of 10⁻¹⁵ to 10⁻²⁰.

In order to minimise the probability that original information is unrecoverable from a block of stored encoded data or that a mis-correct occurs, the preferred embodiments of the invention allow effective use of an error correction coding scheme. Also, it is possible to tolerate a relatively large number of failed symbols within a block of ECC encoded data.

In the preferred embodiments of the invention, failed cells amongst a set of cells of interest in a read operation are predicted, which allows error correction decoding of ECC encoded data stored in the MRAM device to be significantly enhanced. The predicted failures allow erasure information to be formed for a block of ECC encoded data read from the MRAM device 1. The failures can be predicted by any suitable mechanism. As illustrative examples, failed cells can be identified by a parametric test of each cell at read time, or by examining a related set of test cells, or by maintaining a history of parts of the device affected by failures (e.g. identifying rows and/or columns of cells affected by grouped-type failures).

The MRAM device described herein is ideally suited for use in place of any prior solid-state storage device. In particular, the MRAM device is ideally suited both for use as a short-term storage device (e.g. cache memory) or a longer-term storage device (e.g. a solid-state hard disk). An MRAM device can be employed for both short term storage and longer term storage within a single apparatus, such as a computing platform.

A magnetoresistive solid-state storage device and a method for storing data in such a device have been described. Advantageously, the storage device is able to tolerate a relatively large number of errors, including both systematic failures and transient failures, whilst successfully remaining in operation with no loss of original data, through the use of error correction coding. As a result, simpler and lower cost manufacturing techniques are employed and/or device yield and device density are increased. Further, the preferred ECC scheme maintains reliable data storage. Optionally, the preferred ECC scheme is combined with a preferred device layout that enhances physical efficiency.

1. A method for storing data in a solid state storage device having at least one array of magnetoresistive storage cells, the method comprising the steps of:
encoding original data with a Reed-Solomon code to generate one or more codewords including 2T check symbols, using a generator polynomial g(x) of the form:
g(x)=(x+a^{L})(x+a^{L+1})(x+a^{L+2}) . . . (x+a^{L+2T-1})
where 0≦L<255 and T=16; and
storing the one or more codewords in the at least one array of magnetoresistive storage cells.

2. The method of claim 1, wherein L=1.

3. The method of claim 1, wherein L=112.

4. The method of claim 1, comprising dividing a sector of original data into a plurality of sub-sector units, and encoding each sub-sector unit to form one codeword.

5. The method of claim 1, comprising encoding a sector of original data of length 512 bytes to generate four codewords each of length 160 bytes including 128 information symbols and 2T=32 check symbols.

6. The method of claim 5, comprising storing the four codewords in a macro-array having a plurality of arrays of magnetoresistive storage cells.

7. The method of claim 6, comprising storing the four codewords across the macro-array to be accessible substantially simultaneously.

8. The method of claim 1, comprising reading the stored encoded data from the at least one array, and decoding the stored encoded data.

9. A method of encoding data for storage in a solid state storage device comprising a macro-array formed of a plurality of arrays of magnetoresistive storage cells, the method comprising the steps of:
receiving a sector of original data;
dividing the sector of original data into a plurality of sub-sector units;
encoding each sub-sector unit with a Reed-Solomon code to generate a codeword including 2T check symbols, using a generator polynomial g(x) of the form:
g(x)=(x+a^{L})(x+a^{L+1})(x+a^{L+2}) . . . (x+a^{L+2T-1})
where 0≦L<255 and T=16; and
storing the one or more codewords in the macro-array of magnetoresistive storage cells.

10. The method of claim 9, comprising:
retrieving the stored codewords from the macro-array;
decoding each codeword to provide a plurality of sub-sector units of decoded data; and
assembling the decoded sub-sector units to provide a sector unit of decoded data.

11. A solid state storage device comprising:
a Reed-Solomon encoder arranged to encode original data to generate one or more codewords including 2T check symbols, using a generator polynomial g(x) of the form:
g(x)=(x+a^{L})(x+a^{L+1})(x+a^{L+2}) . . . (x+a^{L+2T-1})
where 0≦L<255 and T=16;
at least one array of magnetoresistive storage cells arranged to store the one or more generated codewords; and
a Reed-Solomon decoder arranged to decode the stored one or more codewords to retrieve the original data.

12. The device of claim 11, wherein L=1.

13. The device of claim 11, wherein L=112.

14. The device of claim 11, wherein the encoder is arranged to encode a sector of original data of length 512 bytes to generate four codewords each of length 160 bytes including 128 information symbols and 2T=32 check symbols.

15. The device of claim 14, comprising a macro-array having a plurality of arrays of magnetoresistive storage cells arranged to store the four codewords.

16. The device of claim 15, wherein the macro-array is arranged to store the four codewords, such that at least a reciprocal integer fraction of the four codewords is accessible substantially simultaneously.

17. The device of claim 15, wherein the macro-array comprises at least 320 arrays, each array being arranged to store at least two symbols of the encoded data.

18. A method for storing data in a solid state storage device having at least one array of magnetoresistive storage cells, substantially as hereinbefore described with reference to the accompanying drawings.

19. A solid state storage device substantially as hereinbefore described with reference to the accompanying drawings.
